(19) United States
(12) Patent Application Publication
(10) Pub. No.: US 2005/0208278 A1
(43) Pub. Date: Sep. 22, 2005

(54) Method for improving bonding of circuit substrates to metal and articles formed thereby

(76) Inventors: Vincent R. Landi, Phoenix, AZ (US); Bryan C. McAlister, Phoenix, AZ (US); John T. Neill, Woodstock, CT (US)

Correspondence Address: CANTOR COLBURN, LLP, 55 GRIFFIN ROAD SOUTH, BLOOMFIELD, CT, 06002, US

(21) Appl. No.: 11/076,445

(22) Filed: Mar. 9, 2005

Related U.S. Application Data
(63) Continuation-in-part of application No. 10/225,395, filed on Aug. 21, 2002.
(60) Provisional application No. 60/314,149, filed on Aug. 22, 2001.

(51) Int. Cl. H05K 3/00; B29B 15/10; B32B 31/00

(52) U.S. Cl. 428/209; 428/458; 428/901; 156/307.3

(57) ABSTRACT

A method of forming a circuit material comprises disposing an adhesion promoting elastomer composition between a conductive copper foil and a thermosetting composition; and laminating the copper foil, adhesion promoting composition, and thermosetting composition to form the circuit material. The adhesion promoting layer may be uncured or partially cured before contacting with the curable thermosetting composition. Preferably the adhesion promoting layer has electrical characteristics such as dissipation factor, dielectric breakdown strength, water absorption, and dielectric constant that are similar to and/or compatible with the electrical characteristics of the thermosetting composition.

### CROSS-REFERENCE TO RELATED APPLICATION

This application is a continuation-in-part of U.S. patent application Ser. No. 10/225,395, filed Aug. 21, 2002, which claims priority to U.S. Provisional Application Ser. No. 60/314,149 filed Aug. 22, 2001, which is incorporated by reference herein in its entirety.

### BACKGROUND OF INVENTION

This invention relates to printed circuit board materials comprising conductive metals adhered to circuit board substrates, and in particular to methods for improving the bond strength between the surface of a conductive metal and a substrate in a circuit board.

Circuit board materials are well known in the art, generally comprising a circuit board substrate (dielectric) adhered to a conductive metal surface. Electronic devices that operate at higher frequencies require use of circuit substrates with low dielectric constants and low dissipation factors. In addition, as electronic devices and the features thereon become smaller, manufacture of dense circuit layouts is facilitated by use of substrates with a high glass transition temperature. However, when rigid substrate compositions with low dielectric constants, low dissipation factors, and high glass transition temperatures are used, the resulting circuit material may have low peel strength between the conductive metal surface and the substrate. Peel strength may be even more severely reduced when the conductive metal is a low or very low roughness copper foil. Such foils are desirably used in dense circuit designs.

A number of efforts have been made to improve the bonding between the substrate material and the surface of the metal, which is generally hydrophilic. For example, U.S. Pat. No. 5,904,797 to Kwei discloses using chromium (III) methacrylate/polyvinyl alcohol solutions to improve bonding between thermoset resins and hydrophilic surfaces. The chromium methacrylate chemically bonds the thermoset resin to the hydrophilic surface. While chromium methacrylate is useful for some thermoset resins, it is not useful for all resins, notably polybutadiene and polyisoprene resins. PCT Application No. 96/19067 to McGrath discloses contacting the metal surface with an adhesion promoting composition comprising hydrogen peroxide, an inorganic acid, a corrosion inhibitor, and a quaternary ammonium surfactant.

Use of various specific polymeric compositions have also been disclosed. For example, PCT Application No. 99/57949 to Holman discloses using an epoxy or phenoxy resin having a molecular weight greater than about 4,500 to improve the peel strength of a laminate. U.S. Pat. No. 6,132,851 to Poutasse also discloses use of a phenolic resole resin/epoxy resin composition-coated metal foil as a means to improve adhesion to dielectric substrates. After the coating solution is applied to the foil, the composition must be B-staged (partially cured). The coating weight uptake on the metal foil substrate is abut 20 to 50 g/m², with 25 to 35 g/m² preferred. U.S. Pat. No. 4,954,185 to Kohm describes a two-step process for producing a coated metal foil for PCB laminates, the first being a chemical process to create a metal oxide layer on the metal substrate surface, and the second step being the application of a poly(vinyl acetal)/thermosetting phenolic composition. The thickness of the coating layer is greater than about 20 micrometers, and preferably greater than about 30 micrometers. Gardeski, in U.S. Pat. No. 5,194,307, describes an adhesive composition having one or more epoxy components and a high molecular weight polyester component. In use, this adhesive layer is typically 1 mil (25.4 micrometers) thick. The cured adhesive layer is flexible and can be used for bonding metal foil to flexible circuit substrate (e.g., polyimide film).

Finally, Poutasse and Kovacs, in U.S. Pat. No. 5,622,782 use an multicomponent-organosilane layer to improve foil adhesion with another substrate. The silane treatment on foil is very thin, less than 0.1 micrometer, and the most preferred thicknesses are less than 0.02 micron. Copper foil manufacturers typically apply a silane treatment to their foils as the final production step, and the silane composition, which is often proprietary, is commonly selected to be compatible with the substrate of the customer.

As noted by Poutasse et al. in U.S. Pat. No. 5,629,098, adhesives that provide good adhesion to metal and substrate (as measured by peel strength) generally have less than satisfactory high temperature stability (as measured in the solder blister resistance test). Conversely, adhesives that provide good high temperature stability generally have less than satisfactory adhesion. There accordingly remains a need in the art for methods for improving the bond between a conductive metal and a circuit substrate, particularly thin, rigid, thermosetting substrates having low dielectric constants, dissipation factors, and high glass transition temperatures, that maintain adhesiveness at high temperatures. It would be advantageous if the adhesive did not require B-staging, and it is particularly important that use of the method not adversely affect the electrical and mechanical properties of the resulting circuit materials.

### SUMMARY OF INVENTION

A method for enhancing the adhesion between a copper foil and a circuit substrate comprises disposing an elastomer composition between a surface of the copper foil and a curable circuit substrate composition, and laminating the copper foil, elastomer composition, and curable circuit substrate composition. The elastomer composition is preferably applied in the form of a solution, and can further comprise additives such as viscosity modifiers, coupling agents, wetting agents, flame retardants, fillers, co-curing components, and anti-oxidants. The elastomer composition comprises a non-sulfur curing agent. The elastomer composition may be uncured, partially cured, or fully cured before lamination. The elastomer composition, after lamination, has electrical characteristics such as dissipation factor, dielectric breakdown strength, water absorption, and dielectric constant that do not significantly change the electrical characteristics of the circuit substrate composition.

In another embodiment, a coated copper foil having improved bond strength in a circuit material comprises a copper foil; and the above described adhesion promoting elastomer composition in an amount of about 3 g/m² to about 15 g/m² disposed on a surface of the conductive copper foil.

In another embodiment, a coated copper foil having improved bond strength in a circuit material comprises copper foil and an adhesion promoting elastomer composition in an amount of about 1 g/m² to about 3 g/m² disposed on a surface of the conductive copper foil. In a specific embodiment, the copper foil is a low profile copper foil.

In yet another embodiment, a curable dielectric prepreg having improved bond strength in a circuit material comprises a curable circuit substrate material; and an adhesion promoting elastomer composition disposed on a surface of the substrate composition, wherein the cured circuit substrate material and elastomer composition have a dielectric constant of less than about 3.8 and a dissipation factor of less than about 0.007, each measured at frequencies from 1 to 10 gigahertz.

In another embodiment, a circuit material comprises an adhesion promoting elastomer composition disposed between a copper foil and a cured circuit substrate composition. The circuit material and circuits formed therefrom have superior bond strength when compared to circuit materials that do not employ an adhesion promoting layer comprising an elastomeric polymer or copolymer. The circuit materials and circuits formed therefrom further retain bond after repeated solder exposures, do not blister after solder immersion, and maintain bond strength at elevated temperatures (up to 225° C.). The above-discussed and other features and advantages of the present invention will be appreciated and understood by those skilled in the art from the following detailed description.

### BRIEF DESCRIPTION OF DRAWINGS

Referring now to the exemplary drawings wherein like elements are numbered alike in the several figures:

FIG. 1 shows an exemplary copper foil coated with the adhesion promoting elastomer layer.

FIG. 2 shows an exemplary dielectric material coated with the adhesion promoting elastomer layer.

FIG. 3 shows an exemplary circuit material comprising the adhesion promoting elastomer material.

FIG. 4 shows an exemplary diclad circuit material comprising the adhesion promoting elastomer material.

FIG. 5 shows an exemplary diclad circuit comprising the adhesion promoting elastomer layer.

FIG. 6 shows an exemplary multi-layer circuit comprising an adhesion promoting elastomer layer.

### DETAILED DESCRIPTION

A method for enhancing the adhesion between a copper foil and a curable circuit substrate composition comprises use of an elastomeric polymer composition, preferably an ethylene-propylene-diene monomer elastomer, as an adhesion promoting layer. The elastomer may be applied to the copper foil or the curable substrate composition just prior to lamination, or the elastomer may be applied to the copper foil or the curable substrate composition and stored until needed for lamination. Use of an adhesion promoting elastomer layer results in a significant increase in the bond strength between the copper foil and the curable substrate composition. These results are surprising because as is shown in comparative Examples 5-7 and 9-11, use of various thermosetting resins on the copper foil that would have been expected to have greater compatibility with the foil and curable circuit substrate composition do not, in fact, improve bond strength. The improved bond strength attained in accordance with the present invention is advantageously maintained at high temperatures, such as those that may be encountered during soldering operations (e.g., 550° F., 288° C.).

In another surprising and advantageous feature, use of a suitable elastomer composition does not adversely affect the electrical properties of the resultant circuit material. Suitable elastomeric polymers for use in the elastomer composition include ethylene-propylene elastomer (EPR); ethylene-propylene-diene monomer elastomer (EPDM); styrene-butadiene elastomer (SBR); styrene butadiene block copolymers (SB); 1,4-polybutadiene; other polybutadiene block copolymers such as styrene-isoprene-styrene triblock (SIS), styrene-(ethylene-butylene)-styrene triblock (SEBS), styrene-(ethylene-propylene)-styrene triblock (SEPS), and styrene-(ethylene-butylene) diblock (SEB); polyisoprene; elastomeric acrylate homopolymers and copolymers; silicone elastomers; fluoropolymer elastomers; butyl rubber; urethane elastomers; norbornene and dicyclobutadiene based elastomers; butadiene copolymers with acrylonitrile, acrylate esters, methacrylate esters or carboxylated vinyl monomers; copolymers of isoprene with acrylonitrile, acrylate esters, methacrylate esters or carboxylated vinyl monomers; and mixtures comprising at least one of the foregoing elastomeric polymers.

A preferred elastomeric polymer is ethylene-propylene-diene monomer elastomer. Preferred diene monomers are dicyclopentadiene, 1,4-hexadiene, and ethylidene norbornene. Preferably the ethylene-propylene-diene monomer elastomer has an ethylene content of at least about 30 weight percent (wt %), more preferably at least about 50 wt %, and most preferably at least about 60 wt % of the total weight of the ethylene-propylene-diene monomer elastomer. Preferred ethylene-propylene-diene monomer elastomers have a number average molecular weight (Mₙ) of about 5,000 to about 2,000,000.

The elastomer composition can optionally comprise additives such as cross-linking agents, viscosity modifiers, coupling agents, wetting agents, flame retardants, fillers, co-curing components, and anti-oxidants. The particular choice of elastomer and additives depends upon the nature of the copper foil and the curable circuit substrate composition, and is preferably selected so as to result in good adhesion between the copper foil and the curable circuit substrate composition, and for the combination of elastomer and substrate composition to have a dielectric constant of less than about 3.8 and a dissipation factor of less than about 0.007, each measured at frequencies from 1 to 10 gigahertz (GHz). Preferably, the dielectric constant and dissipation factor of the elastomer composition are within about 25%, more preferably within about 10% of the corresponding values for the circuit material. In addition, it is preferred that other physical properties such as dielectric breakdown strength and water absorption are similar to and/or compatible with the electrical characteristics of the circuit material, preferably within about 25%, more preferably within about 10% of the corresponding values for the circuit material.

Examples of preferred fillers for use in the adhesion promoting layer include titanium dioxide (rutile and anatase), barium titanate, strontium titanate, silica, including fused amorphous silica, corundum, wollastonite, aramide fibers (e.g., KEVLAR™ from DuPont), fiberglass, Ba₂Ti₉O₂₀, glass spheres, quartz, boron nitride, aluminum nitride, silicon carbide, beryllia, alumina or magnesia, fumed silicon dioxide (e.g., Cab-O-Sil, available from Cabot Corporation), used alone or in combination. The above named particles may be in the form of solid, porous, or hollow particles. Particularly preferred fillers are rutile titanium dioxide and amorphous silica. To improve adhesion between the fillers and polymer, the filler may be treated with one or more coupling agents, such as silanes, zirconates, or titanates. Fillers, when present, are typically present in an amount of greater than or equal to about 1 part per hundred of elastomer by weight (phr), with greater than or equal to about 2 phr preferred, and greater than or equal to about 5 phr more preferred. Fillers are typically present in an amount of less than or equal to about 40 phr, with less than or equal to about 15 phr preferred, and less than or equal to about 10 phr more preferred.

Suitable cross-linking agents include those useful in cross-linking elastomeric polymers, especially those useful in cross-linking ethylene-propylene-diene monomer elastomers. Examples include, but are not limited to, azides and peroxides. Free radical initiators are preferred as cross-linking agents. Examples of free radical initiators include peroxides, hydroperoxides, and non-peroxide initiators such as 2,3-dimethyl-2,3-diphenyl butane. Preferred peroxide cross-linking agents include dicumyl peroxide, alpha, alpha-di(t-butylperoxy)-m,p-diisopropylbenzene, 2,5-dimethyl-2,5-di(t-butylperoxy)hexane-3, and 2,5-dimethyl-2,5-di(t-butylperoxy)hexyne-3, and mixtures comprising one or more of the foregoing cross-linking agents. The cross-linking agent, when used, is typically present in an amount of about 1 to about 15 phr. Although use of sulfur is taught in the prior art as a curative in electronic materials, sulfur and sulfur derivatives are not suitable for the application due to their reactivity toward the copper foil. It is known, for example, that sulfur compounds can migrate with time and cause unwanted corrosion of copper in electrical circuitry.

Co-curing components are reactive monomers with unsaturation or polymers such as 1,2-polybutadiene polymers, which may be included in the solution for a specific property or for specific processing conditions. Inclusion of one or more co-curing components has the benefit of increasing cross-link density upon cure. Suitable reactive monomers are capable of co-reacting with the elastomeric polymer and/or the circuit substrate composition. Examples of suitable reactive monomers include styrene, divinyl benzene, vinyl toluene, divinyl benzene, triallylcyanurate, diallylphthalate, and multifunctional acrylate monomers (such as Sartomer compounds available from Sartomer Co.), among others, all of which are commercially available. Useful amounts of co-curing components are about 0.1 phr to about 50 phr.

Useful antioxidants include radical scavengers and metal deactivators. A non-limiting example of a free radical scavenger is poly[6-(1,1,3,3-tetramethylbutyl)amino-s-triazine-2,4-dyil][(2,2,6,6,-tetramethyl-4-piperidyl)imino]hexamethylene[(2,2,6,6-tetramethyl-4-piperidyl)imino]] commercially available from Ciba Chemicals under the tradename Chimmasorb 944. A non-limiting example of a metal deactivator is 2,2-oxalyldiamido bis[ethyl 3-(3,5-di-t-butyl-4-hydroxyphenyl)propionate] commercially available from Uniroyal Chemical (Middlebury, Conn.) under the tradename Naugard XL-1. The antioxidant may comprise a single component or a mixture of two or more components. Antioxidants are typically used in amounts of up to about 3 phr, with about 0.5 phr to about 2.0 phr preferred.

When used in solution, wetting agents may be useful additives to improve wetting, promote adhesion or both. Examples of these materials include, but are not limited to, polyether polysiloxane blends such as Coat-O-Sil 1211 (available from Witco) and BYK 333 (available from BYK Chemie), and fluorine-based wetting agents such as Zonyl FSO-100 (available from DuPont). Such wetting agents may be used in amounts of about 0.1 wt % to about 2 wt % of the total weight of the elastomer solution.

Coupling agents may be present to promote the formation of or participate in covalent bonds connecting a metal surface or filler surface with the polymer. Exemplary coupling agents include 3-mercaptopropylmethyldimethoxysilane and 3 mercaptopropyltrimethoxysilane. Coupling agents, when present, may be added in amounts of about 0.1 wt % to about 1 wt % of the total weight of the elastomer solution.

Suitable copper foils include those presently used in the formation of circuits, for example, electrodeposited copper foils. Useful copper foils typically have thicknesses of about 9 to about 180 micrometers. Copper foils can also be treated to increase surface area, treated with a stabilizer to prevent oxidation of the foil (i.e., stain-proofing), or treated to form a thermal barrier. Both low and high roughness copper foils treated with zinc or zinc alloy thermal barriers are particularly useful, and may further optionally comprise a stain-proofing layer. Such copper foils are available from, for examples, Yates Foil, USA under the trade names “TWX” and “TW”, Oak-Mitsui under the tradename “TOB”, Circuit Foil Luxembourg under the tradename “TWS”, and Gould Electronics under the tradename “JTCS”. Other suitable copper foils are available from Yates Foil under the trade name “TAX”; from Circuit Foil Luxembourg under the trade name “NT TOR”; from Co-Tech Copper Foil Company under the trade name “TAX”; and from Chang Chun Petrochemical Company under the trade name “PINK”.

Generally, copper foils can have a low profile surface roughness or a “standard” (non-low profile) surface roughness. The term “surface roughness” as used herein to describe copper foils represents the root mean square value of the difference in measured height (here, expressed in micrometers) of a set of “peaks” and “valleys” on the non-glossy, “matte” side of the copper foil. Typical means of measuring surface roughness include stylus profilometry, and laser interferometry. A non-low profile surface roughness may be commonly referred to in the art as “standard profile” copper foil, having a surface roughness of greater than or equal to about 10.2 micrometers. By comparison, as used in the art a “low profile” (“LP”) copper foil has a surface roughness about 5.1 to about 10.2 micrometers; and very low profile (“VLP”) copper foil has a surface roughness of less than about 5.1 micrometers, for example about 5 to about 2 micrometers. Even lower profile foils copper may be available. In an embodiment, a suitable copper foil is a low profile copper foil.

In general and as commonly referred to in the art, copper foils may be described by the approximate weight of copper in ounces (“oz.”) per square foot, wherein the weight per square foot correlates to a thickness of the copper foil in micrometers. In this way, copper foils of about 70 micrometers thickness are commonly referred to as 2 oz. copper foils; copper foils of about 35 micrometers are commonly referred to as 1 oz. copper foils; copper foils of about 17 to about 18 micrometers are commonly referred to as 1/2 oz copper foils; copper foils of about 7 to about 9 micrometers are commonly referred to as 1/4 oz copper foils; and the like. Copper foils may also be obtained in thinner forms, to a thickness of at least 3 micrometers, and in thicker forms, with a thickness greater than 70 micrometers. In an embodiment, copper foils suitable for use herein can have a thickness of greater than 9 micrometers, and specifically greater than 15 micrometers. In a specific embodiment, a copper foil has a thickness of 17 to 180 micrometers, or in the alternative expression, the copper foil has a weight of 1/2 oz. to 5 oz.

Copper foils of specific thicknesses may be obtained with specific surface roughnesses. In this way, copper foils having a thickness of greater than or equal to 17 micrometers can have a standard profile surface roughness of greater than or equal to about 10.2 micrometers, a low profile surface roughness of about 5.1 to about 10.2 micrometers, or a very low profile of less than about 5.1 micrometers; copper foils having thicknesses of about 7 to about 18 micrometers can have a surface roughness can have a standard profile surface roughness of greater than or equal to about 10.2 micrometers (depending on the actual thickness), a low profile surface roughness of about 5.1 to about 10.2 micrometers, or a very low profile of less than about 5.1 micrometers; and copper foils having thicknesses of less than about 9 micrometers can have a low profile surface roughness of about 5.1 to about 10.2 micrometers (depending on thickness), or a very low profile of less than about 5.1 micrometers, for example about 2 to about 3 micrometers, about 1 to about 2 micrometers, or even less. Overlap in thickness ranges reflect variations in specifications as used by manufacturers of copper foils. In an embodiment, a suitable copper foil has a thickness of 17 to 180 micrometers and a low profile surface roughness of less than or equal to about 10 micrometers.

Suitable circuit substrates include thermosetting resins such as 1,2-polybutadiene, polyisoprene, polyester, acrylate ester, polybutadiene-polyisoprene copolymers, allylated polyphenylene ether resins, and thermoplastic resins such as polyphenylene ether (PPE) resins, bismaleimide triazene (BT) resins, epoxy resins, cyanate ester resins, and combinations comprising at least one of the foregoing resins. Mixtures of thermosetting resins and thermoplastics may also be used, non-limiting examples including epoxy-impregnated polytetrafluoroethylene (PTFE), epoxy-coated PTFE, epoxy-polyphenylene ether, epoxy-polyetherimide (PEI), cyanate ester-PPE, and 1,2-polybutadiene-polyethylene. Compositions containing polybutadiene, polyisoprene, and/or polybutadiene and polyisoprene copolymers are especially preferred. The circuit substrate may also include particulate fillers, fabric, elastomers, flame retardants, and other components known in the art.

Particularly preferred circuit substrates are RO4350B and RO4003, both available from Rogers Corporation, Rogers, CT, processed as described in U.S. Pat. No. 5,571,609 to St. Lawrence et al., which is herein incorporated by reference. These thermosetting compositions generally comprises: (1) a polybutadiene or polyisoprene resin or mixture thereof; (2) an optional unsaturated butadiene- or isoprene-containing polymer capable of participating in cross-linking with the polybutadiene or polyisoprene resin during cure; (3) an optional low molecular weight polymer such as ethylene propylene rubber or ethylene-propylene-diene monomer elastomer; and (4) optionally, monomers with vinyl unsaturation.

The polybutadiene or polyisoprene resins may be liquid or solid at room temperature. Liquid resins may have a molecular weight greater than or equal to about 5,000, but preferably have a molecular weight of less than or equal to about 5,000. The preferably liquid (at room temperature) resin portion maintains the viscosity of the composition at a manageable level during processing to facilitate handling, and it also cross-links during cure. Polybutadiene and polyisoprene resins having at least about 90% 1,2-addition by weight are preferred because they exhibit the greatest cross-link density upon cure owing to the large number of pendant vinyl groups available for cross-linking.

The thermosetting composition optionally comprises functionalized liquid polybutadiene or polyisoprene resins. Examples of appropriate functionalities for butadiene liquid resins include but are not limited to epoxy, maleate, hydroxy, carboxyl and methacrylate. Examples of useful liquid butadiene copolymers are butadiene-co-styrene and butadiene-co-acrylonitrile. The optional, unsaturated polybutadiene- or polyisoprene-containing copolymer can be liquid or solid. It is preferably a solid, thermoplastic elastomer comprising a linear or graft-type block copolymer having a polybutadiene or polyisoprene block, and a thermoplastic block that preferably is styrene or α-methyl styrene. The unsaturated butadiene- or isoprene-containing polymer may also contain a second block copolymer similar to the first except that the polybutadiene or polyisoprene block is hydrogenated, thereby forming a polyethylene block (in the case of polybutadiene) or an ethylene-propylene copolymer (in the case of polyisoprene). When used in conjunction with the first copolymer, materials with enhanced toughness can be produced. Where it is desired to use this second block copolymer, a preferred material is Kraton GX1855 (commercially available from Shell Chemical Corp.), which is believed to be a mixture of styrene-high 1,2 butadiene-styrene block-copolymer and styrene-(ethylene-propylene)-styrene block copolymer.

The volume to volume ratio of the polybutadiene or polyisoprene resin to butadiene- or isoprene-containing polymer preferably is between 1:9 and 9:1, inclusive. The selection of the butadiene- or isoprene-containing polymer depends on chemical and hydrolysis resistance as well as the toughness conferred upon the laminated material.

The optional low molecular weight polymer resin is generally employed to enhance toughness and other desired characteristics of composition. Examples of suitable low molecular weight polymer resins include, but are not limited to, telechelic polymers such as polystyrene, multifunctional acrylate monomers, EPR, or EPDM containing varying amounts of pendant norbornene groups and/or unsaturated functional groups. The optional low molecular weight polymer resin can be present in amounts of about 0 to about 30 wt % of the total resin composition.

Monomers with vinyl unsaturation may also be included in the resin system for specific property or processing conditions, such as to decrease viscosity, and has the added benefit of increasing cross-link density upon cure. Examples of suitable monomers include styrene, vinyl toluene, divinyl benzene, triallylcyanurate, diallylphthalate, and multifunctional acrylate monomers (such as Sartomer compounds available from Arco Specialty Chemicals Co.), among others, all of which are commercially available. The useful amount of monomers with vinyl unsaturation is about 0 to about 80 wt % of the total resin composition and preferably about 3 wt % to about 50 wt % of the total resin composition.

A non-sulfur containing curing agent is preferably added to the resin system to accelerate the curing reaction. Preferred curing agents are organic peroxides such as dicumyl peroxide, t-butyl perbenzoate, 2,5-dimethyl-2,5-di(t-butyl peroxy)hexane, α,α-di-bis(t-butyl peroxy)diisopropylbenzene, and 2,5-dimethyl-2,5-di(t-butyl peroxy)hexyne-3, all of which are commercially available. They may be used alone or in combination. Typical amounts of curing agent are from about 1.5 phr to about 10 phr of the total resin composition.

In practice, the elastomer composition (elastomeric polymer plus any additional additives) is dissolved and/or suspended in solution for ease of application to a surface of the copper foil or substrate composition (such substrate compositions being, e.g., in the form of a prepreg). The solvent is chosen so as to dissolve the elastomeric polymer, and is also preferably of low toxicity and has a convenient evaporation rate for applying and drying the coating. A non-inclusive group of possible solvents include: xylene, toluene, methyl ethyl ketone, methyl isobutyl ketone, hexane and higher liquid linear alkanes, such as heptane, octane etc, cyclohexane, isophorone, and various terpene based solvents. A preferred solvent is xylene. The amount of elastomer in solution is not critical, and will depend on solubility, methods of application, and similar factors, such that the solution may comprise greater than or equal to about 1, and less than or equal to about 99 wt % elastomer, based on the total weight of the elastomer solution.

In one embodiment, the elastomer composition is applied to a surface of the copper foil by dip-, spray-, wash-, or other coating technique to provide an adhesion promoting layer that optimizes bond strength and other characteristics such as electrical properties and resistance to attack by organic solvents. Typically the coating has a weight of about 3 g/m² (grams per square meter) to about 15 g/m², preferably about 4 g/m² to about 8 g/m². Where a solvent is present, the elastomer solution is allowed to dry under ambient conditions, or by forced or heated air, to form an adhesion promoting layer. The adhesion promoting layer may be uncured, partially cured, or fully cured in the drying process, or the adhesion promoting layer may be partially cured, if desired, by other methods known in the art after drying. The circuit substrate material, preferably in the form of a prepreg, is applied to the adhesion promoting layer on a side opposite the copper foil, and the combination of copper foil, adhesion promoting layer, and substrate is laminated by an effective quantity of heat and pressure. Lamination bonds the layers and cures the adhesion promoting layer and the substrate. Particular lamination temperatures and pressures will depend upon the particular elastomer and substrate compositions, and are readily ascertainable by one of ordinary skill in the art.

In another embodiment, the elastomer composition is applied to the circuit substrate material, e.g., a prepreg, to form an adhesion promoting coating. Typically the coating has a weight of about 3 g/m² to about 15 g/m², preferably about 4 g/m² to about 8 g/m². Where a solvent is present, the elastomer solution is allowed to dry under ambient conditions, or by forced or heated air. The adhesion promoting layer may be uncured, partially cured, or fully cured in the drying process, or the adhesion promoting layer may be partially or fully cured, if desired, by other methods known in the art after drying. A copper foil is then disposed on the adhesion promoting layer on a side opposite the substrate layer. A laminated material is formed by an effective quantity of heat and pressure, which again will depend upon the particular circuit substrate material.

In a further embodiment, a very thin layer of the elastomer composition is applied to either one of a surface of the copper foil by dip-, spray-, wash-, or other coating technique, or to the circuit substrate material, to provide an adhesion promoting coating. Specifically the coating is applied to provide a weight of about 1 to less than about 3 grams per square meter (g/m²), specifically about 1.5 g/m² to about 2.5 g/m². The copper foil, adhesion promoting coating, and circuit substrate material may be laminated as described above. Particular lamination temperatures and pressures will depend upon the particular elastomer and substrate compositions, and are readily ascertainable by one of ordinary skill in the art.

Use of very thin adhesion promoting coatings can minimize the effect of the adhesion promoting layer on the dielectric constant and dissipation factors of the circuit material.

In one embodiment, it has been unexpectedly found that the peel strength of a copper foil adhered to a circuit substrate is improved, wherein a loading of about 1 gram per square meter to about 3 g/m² of an adhesion promoting coating, as described above, is used to adhere the matte surface of a low profile copper foil to a circuit substrate. Specifically, where a low profile copper foil is used, an improvement in peel strength of about 1 to about to about 160%, specifically about 10 to about 130%, more specifically about 30 to about 120%, more specifically about 40 to about 100%, even more specifically about 45 to about 90% may be achieved.

By using the above described method a circuit material with excellent properties may be obtained comprising a copper foil, an adhesion promoting elastomeric layer, and a circuit substrate layer, wherein the resultant circuit material has a dielectric constant of less than about 3.8 and a dissipation factor of less than about 0.007, each measured at frequencies from 1 to 10 gigahertz. Significantly, it is possible to have a circuit material with improved bond strength that is retained at elevated temperatures and in which the dielectric properties of the combination of the adhesion promoting layer together with the circuit substrate are the same or similar to the dielectric properties of the circuit substrate composition alone. Use of an adhesion promoting layer comprising an elastomeric polymer or copolymer as described above typically resulted in increased peel strength of at least about 1.0, preferably about 1.5 pound per linear inch (pli) on 1/2-ounce copper. The circuit material further retains bond after repeated solder exposures, does not blister after solder immersion, and maintains bond strength at elevated temperatures (up to 225° C.).

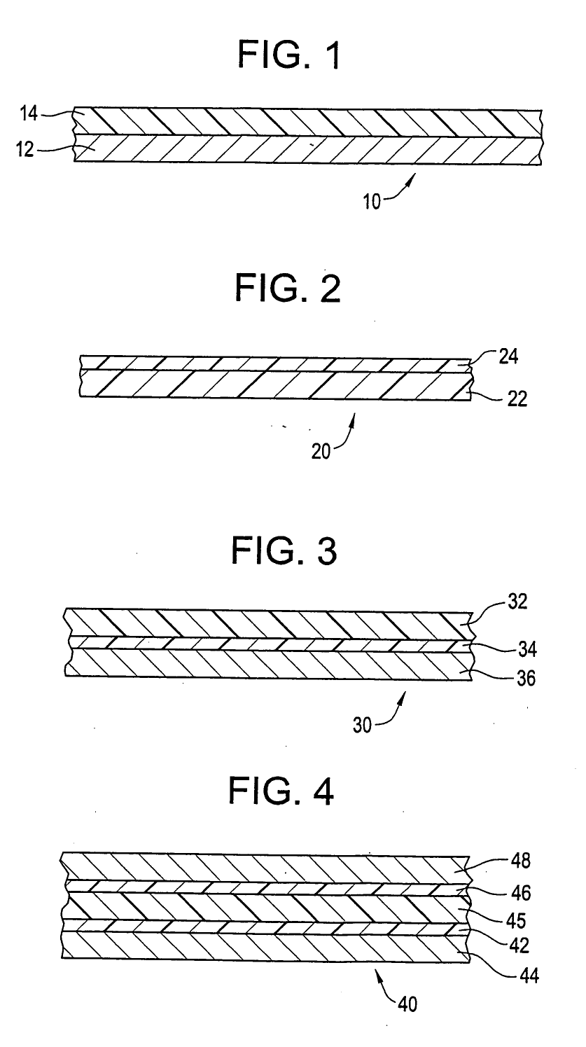

In accordance with various preferred embodiments of the present invention, FIG. 1 shows an exemplary coated copper foil 10 comprising adhesion promoting elastomer layer 14 disposed on and intimate contact with copper foil 12. It is to be understood that in all of the embodiments described herein, the various layers may fully or partially cover each other, and additional copper foil layers, patterned circuit layers, and dielectric layers may also be present in the above-described embodiments.

FIG. 2 shows an exemplary circuit material 20 comprising a circuit substrate 22 disposed on and in intimate contact with an adhesion promoting elastomer layer 24.

FIG. 3 shows an exemplary circuit material 30 comprising a circuit substrate 32 disposed on a first side of an adhesion promoting layer 34, wherein the second side of the adhesion promoting layer 34 is disposed on copper foil 36.

FIG. 4 shows an exemplary diclad circuit material 40 comprising a first adhesion promoting elastomer layer 42 disposed between a first copper foil 44 and a first side of circuit substrate 45. Second adhesion promoting layer 46 is disposed between second copper foil 48 and a second side of circuit substrate 45. The first and second adhesion promoting layers 42, 46 may comprise the same or different elastomer composition, and first and second copper foils 44, 48 may comprise the same or different types of copper foil. It is also possible to use only one of the adhesion promoting elastomer layers 42, 46, or to substitute one of adhesion promoting layers 42, 43 with a bond ply as is known in the art (not shown).

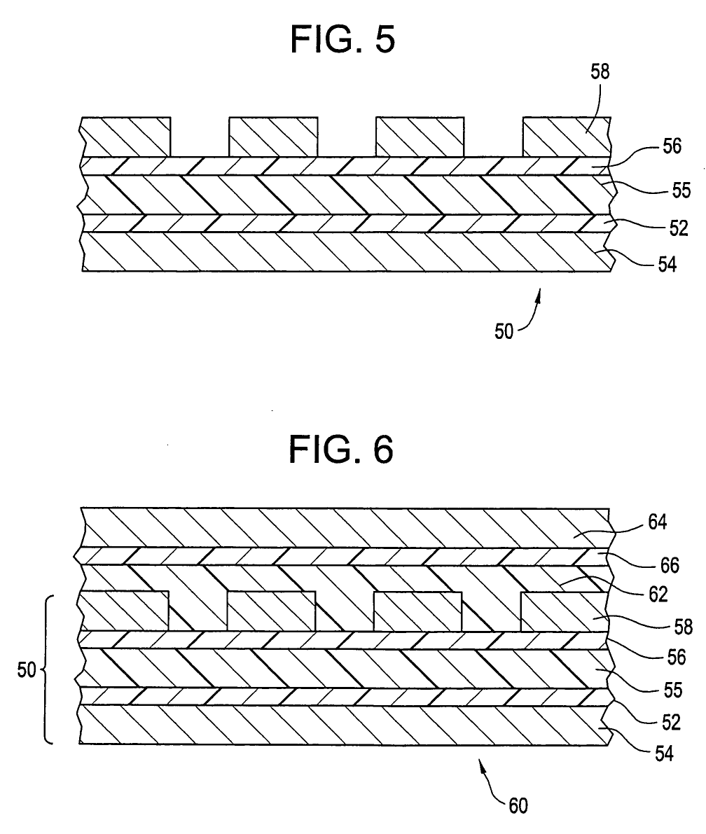

FIG. 5 shows an exemplary diclad circuit 50 comprising a first adhesion promoting elastomer layer 52 disposed between a first copper foil 54 and a first side of circuit substrate 55. Second adhesion promoting layer 56 is disposed between a patterned (e.g., etched) circuit layer 58 and a second side of circuit substrate 55. The first and second adhesion promoting layers 52, 56 may comprise the same or different elastomer composition. It is also possible to use only one of the adhesion promoting elastomer layers 52, 56, or to substitute one of adhesion promoting layers 52, 56 with a bond ply as is known in the art (not shown).

FIG. 6 shows an exemplary multi-layer circuit 60 comprising the circuit material 50 as described in FIG. 5. A bond ply 62 may be disposed on the side of the patterned circuit 58 opposite elastomer layer 56, and a copper foil 64 disposed on bond ply 62 on a side opposite patterned circuit 58. Optionally, and as shown in FIG. 6, a third adhesion promoting elastomer layer 66 is disposed between bond ply 62 and copper foil 64. The first, second, and third adhesion promoting layers 52, 56, 62, may comprise the same or different elastomer composition, and first and second copper foils 54, 64 may comprise the same or different types of copper foil.

The invention is further illustrated by the following non-limiting Examples.

### EXAMPLES

The materials listed in Tables 1A and 1B were used in the following examples.

TABLE 1A

| Trade name | Chemical name | Supplier |
|---|---|---|
| Lupersol 130 | 2,5-Dimethyl-2,5-di(t- | Atochem N. A. |
| | butylperoxy)hexyne-3 | |
| Royalene 301T | Ethylene-propylene-diene monomer | Uniroyal, Inc. |
| | elastomer | |
| Royalene 551 | Ethylene-propylene-diene monomer | Uniroyal, Inc. |
| | elastomer | |
| Trilene 77 | Ethylene-propylene-diene monomer | Uniroyal, Inc. |
| | elastomer | |
| Royaledge X4191 | Ethylene-propylene-diene monomer | Uniroyal, Inc. |
| | elastomer | |
| Vistalon 707 | Ethylene-propylene elastomer | ExxonMobil |
| Kraton D1118X | Styrene-butadiene diblock polymer | Shell Chemical |
| | containing 30% styrene | |
| Taktene 1220 | Cis-1,4 polybutadiene | Bayer |
| A-174 | Gamma- | OSi Specialties |
| | methacryloxypropyltrimethoxysilane | |
| A-189 | Gamma- | OSi Specialties |
| | mercaptopropyltrimethoxysilane | |
| Vulcup | Alpha, alpha-di(t-butylperoxy)-m,p- | Elf Atochem |
| | diisopropylbenzene | |
| B-3000 | High-1,2-vinyl polybutadiene | Nisso |
| Cab-O-Sil TS-720 | Dimethyl silicone treated fumed | Cabot Corp. |
| | silica | |
| Cab-O-Sil TS-530 | Hexamethyldisilazane treated | Cabot Corp. |
| | fumed silica | |
| BLS-1944 | Hindered amine light stabilizer | Mayzo |
| Saytex BT-93 | ethylenebistetrabromophthalimide | Albermarle |
| Naugard Q | antioxidant | Uniroyal |

Table 1B shows the roughness characteristics of foils used in the examples. Mean Roughness depth (Rz) is calculated by measuring the vertical distance from the highest peak to the lowest valley within five sampling lengths, then averaging these distances, using the contacting stylus technique. Rz averages only the five highest peaks and the five deepest valleys. Extremes therefore have a much greater influence on the final value.

TABLE 1B

| Grade | Thickness, micrometers | Manufacturer | Rz, micrometers |
|---|---|---|---|
| TAX | 0.5-oz | Yates, Cotech | 5.1-10.2 |
| TWX | 0.5-oz | Yates | 5.1-10.2 |
| TWS | 0.5-oz | Circuit Foil | 5.1-10.2 |
| TOR | 0.5-oz | Circuit Foil | 5.1-10.2 |
| MQ-VLP | 0.5-oz | Mitsui | 4.5 |
| 3EC | 0.5-oz | Mitsui | 3 |
| 3EC | 1.0-oz | Mitsui | 5 |

### Example 1

A 10 wt % solution of Royalene 301T in xylene was prepared. Five parts of Lupersol 130 per 100 parts of Royalene 301T was added to the solution. The solution was applied to 0.5 oz. copper foil (TAX available from Yates Foil, treated by the manufacturer with silane). The coated copper foil was dried under ambient conditions to form an adhesion promoting layer. The weight of the adhesion promoting layer was approximately 5.9 grams per square meter. An RO4350B prepreg (a polybutadiene-based thermosetting composition available from Rogers Corporation, Rogers CT) was applied and heated under pressure to effect lamination. Lamination conditions were as follows:
Initial conditions were 93° C. (200° F.) and 6.9 Mega Pascals (MPa) (1000 pounds per square inch (psi)).
Temperature was ramped from 93° C. to 174° C. (345° F.) at 1.1° C. (2° F.) per minute;
Dwell at 174° C. for 15 minutes;
Ramp to 246° C. (475° F.) at 4.7° C. (7.6° F.) per minute;
Dwell at 246° C. for 90 minutes;
Drop pressure to 400 psi and ramp down temperature to 204° C. (400° F.) at 2.8° C. (5° F.) per minute;
Dwell at 204° C. for 60 minutes; and
Ramp down to 93° C. at 2.8° C. per minute.

### Example 2

Example 2 was prepared as in Example 1 except the 0.5 oz. foil employed was TWX copper foil, also available from Yates Foil. TWX foil is manufactured with a zinc treatment (thermal barrier) on the matte side of the foil. The copper foil side having the zinc treatment was placed in contact with the adhesion promoting layer.

### Example 3

Example 3 was prepared as in Example 1 except the elastomeric polymer employed was Royalene 551 and the TAX foil had no manufacturer applied silane.

### Example 4

Example 4 is a comparative example that was prepared as in Example 1 without the adhesion promoting layer. Results for examples 1-4 are shown in Table 2. Peel strength was tested in accordance with IPC-TM-650 2.4.8.

TABLE 2

| Example | Coating | Copper type | Peel Strength, pli |
|---|---|---|---|
| 1 | Royalene 301 | TAX | 5.47 |
| 2 | Royalene 301 | TWX | 5.84 |
| 3 | Royalene 551 | TAX (without silane) | 7.94 |
| 4* | none | TAX | 3.69 |

*Control

As can be seen from the data in Table 2, use of an adhesion promoting layer comprising elastomeric polymer or copolymer results in a 48% or greater increase in bond strength.

### Examples 5-12

Examples 5-12 are comparative examples not within the scope of the invention. The examples were prepared as described in Example 1 except that in Examples 5-7 and 9-11, B-3000, a liquid 1,2-polybutadiene resin, was used in place of Royalene 301 and Royalene 551. B-3000 thermosetting resin is known to produce a hard, resinous coating when cured. Examples 5-7 were made using differing thicknesses of the B-3000 coating on TWX foil. Examples 9-11 were made using differing thicknesses of the B-3000 coating on TAX foil. Example 8 employed no coating on TWX foil. Example 12 employed no coating on TAX foil. Thickness of the coating in the various examples as well as the peel strength are shown in Table 3.

TABLE 3

| Example | Copper Type | Coating Weight, g/m² | Peel strength, pli |
|---|---|---|---|
| 5 | TWX | 3.55 | 4.25 |
| 6 | TWX | 4.68 | 4.08 |
| 7 | TWX | 5.71 | 4.08 |
| 8* | TWX | 0 | 4.13 |
| 9 | TAX | 2.79 | 3.65 |
| 10 | TAX | 3.43 | 3.63 |
| 11 | TAX | 4.29 | 3.56 |
| 12* | TAX | 0 | 3.66 |

*Control for the comparative examples

Comparative examples 5-7 and 9-11 demonstrate that an increase in bond strength cannot be achieved by simply coating the copper with a non-elastomeric resin, even a resin that is compatible and chemically similar to the curable thermosetting composition.

### Example 13

An 8 wt % solution of Royaledge X4191 in xylene was prepared. Added to this solution were 8 phr Lupersol 130, 6 phr Cab-O-Sil TS-720, and 1 phr Mayzo BLS 1944. The solution was applied to 0.5 oz. Cotech (Taiwan) TAX copper foil. The coated copper foil was dried under ambient conditions to form an adhesion promoting layer. An RO4350B prepreg was applied and heated under pressure to effect lamination.

### Example 14

Example 14 was prepared as in Example 13 except the Cab-O-Sil grade was TS-530.

### Example 15A

Example 15 is a comparative example that was prepared as in Example 13 without the adhesion promoting layer. Results for Examples 13-15 are shown in Table 4.

TABLE 4A

| Example | Adhesion promoting Layer | Peel strength, pli |
|---|---|---|
| 13 | yes | 6.7 |
| 14 | yes | 6.3 |
| 15* | no | 3.6 |

*Control

As shown in Table 4, an increase in bond strength is observed when the adhesion promoting layer contains filler. The increase in bond strength is similar for two different types of coated fumed silicon dioxide fillers.

### Example 15B

Using the same coating as described in Example 13, the effect of coating on peel strength of a VLP (‘very low profile’) foil was investigated. Mitsui MQ-VLP is a very low profile copper foil with a matte side roughness of approximately 4.5 micrometers. The copper bond of this foil to RO4350B substrate is 2.8 pli. The coating solution from Example 13 was applied to this foil to provide foils having dry coating weights from 1.5-gsm to 3-gsm. These foils were laminated to RO4350B prepreg. The peel strength results are shown in Table 4B.

TABLE 4B

| | | Relative increase in bond |
|---|---|---|
| Dry coating weight on | | strength (compared to no |
| copper foil, gsm | Peel strength, pli | coating on copper foil) |
| 0* | 2.8 | 1.00 |
| 1.5 | 4.2 | 1.50 |
| 2.0 | 4.6 | 1.64 |
| 2.5 | 4.8 | 1.71 |
| 3.0 | 5.1 | 1.82 |

*Control

As can be seen from the above data, the present invention provides significantly enhanced bond to copper.

### Example 16

A 7 wt % solution of Vistalon 707 in xylene was prepared. Added to this solution were 6 phr Lupersol 130, 6 phr Cab-O-Sil TS-530, and 1 phr Mayzo BLS 1944. The solution was applied to 0.5 oz. Circuit Foil (Luxembourg) TOR copper foil. The coated copper foil was dried under ambient conditions to form as adhesion promoting layer. An RO4350B prepreg was applied and heated under pressure to effect lamination.

### Example 17

Example 17 is a comparative example that was prepared as in Example 16 without the adhesion promoting layer on the TOR foil. Results for examples 16 and 17 are shown in Table 5.

TABLE 5

| Example | Coating weight, g/m² | Peel strength, pli |
|---|---|---|
| 16 | 3.9 | 5.3 |
| 17* | 0 | 3.4 |

*Control

The data in Table 5 illustrate that the increase in peel strength observed with the use of adhesion promoting layers is observed for ethylene-propylene elastomer as well as EPDM.

### Example 18

An 8 wt % solution of Royalene 551/Royalene 301T (70/30, by weight) in xylene was prepared. Added to this solution were 5 phr Lupersol 130, 20 phr Saytex BT-93, and 1 phr Mayzo BLS 1944. The solution was applied to 0.5 oz. Circuit Foil (Luxembourg) TWS copper foil. The coating was applied by slot die and then dried in a forced-air oven. An RO4350B prepreg was applied and heated under pressure to effect lamination.

### Example 19

An 8 wt % solution of Royalene 551/Royalene 301T (70/30, by weight) in xylene was prepared. Added to this solution were 6 phr Lupersol 130, 6 phr Cab-O-Sil TS-720, and 1 phr Mayzo BLS 1944. The solution was applied to 1-oz. Mitsui 3EC copper foil. The coating was applied by slot die and then dried in a forced-air oven. An RO4350B prepreg was applied and heated under pressure to effect lamination.

### Example 20

Example 20 was prepared as in Example 19 except the foil coated was 0.5-oz Mitsui 3EC.

### Example 21

Example 21 was prepared as in Example 19 except the foil coated was 0.5-oz Cotech TAX. The data for Examples 18-21 are shown in Table 6.

TABLE 6

| | | Foil coating | |
|---|---|---|---|
| Example | Copper foil | weight, g/m² | Peel strength, pli |
| 18 | 0.5-oz Circuit Foil TWS | 6.9 | 6.7 |
| 19 | 1-oz Mitsui 3EC | 6.5 | 7.5 |
| 20 | 0.5-oz Mitsui 3EC | 6.4 | 5.5 |
| 21 | 0.5-oz Cotech TAX | 7.1 | 6.5 |

The same 0.5-oz copper foils used in Examples 18 through 21 without the adhesion promoting layer do not provide bond strength greater than 4 pli when used with an RO4350B substrate. Thus, the presence of an adhesion promoting layer can increase peel strength by as much as 2.5-3.5 pli or more on a variety of copper foils.

### Example 22

An 8 wt % solution of Royalene 551/Royalene 301T (70/30, by weight) in xylene was prepared. Added to this solution were 5 phr Lupersol 130, 20 phr Saytex BT93, and 2 phr Mayzo BLS 1944. The solution was applied to 0.5-oz Circuit Foil TWS copper foil. The coating was applied by slot die and then dried in a forced-air oven. A polyethylene-woven glass prepreg was applied and heated under pressure to effect lamination.

### Example 23

Example 23 is a comparative sample, and was prepared as in Example 22 except the TWS foil was not coated with an adhesion promoting layer. The data for Examples 22 and 23 are shown in Table 7.

TABLE 7

| Example | Coating weight, g/m² | Peel strength, pli |
|---|---|---|
| 22 | 6.2 | 2.8 |
| 23* | 0 | 1.1 |

*Control

Examples 22 and 23 show that use of an adhesion promoting layer can improve the adhesion between a copper foil and a substrates such as a polyethylene-woven glass prepreg.

### Examples 24-28

Examples 24 through 28 demonstrate the effect of filler (Cab-O-Sil) on bond strength. An 8 wt % solution of Royalene 551/Royalene 301T (70/30, by weight) in xylene was prepared. Added to this solution were 5 phr Lupersol 130, 20 phr Saytex BT93, and 2 phr Mayzo BLS 1944. Cab-O-Sil TS-720 was also added in the range of 0 phr to 8 phr, in 2 phr increments, to produce the coating solutions for Examples 24 to 28. The coatings were applied to 0.5-oz Circuit Foil TWS and the coating was allowed to air dry. An RO4350B prepreg was applied and heated under pressure to effect lamination.

### Example 29

Example 29 is a comparative sample, and was prepared as in Example 24 except the 0.5-oz TWS foil is not coated with an adhesion promoting layer. The results of Examples 28-29 are shown in Table 8.

TABLE 8

| Example | Cab-O-Sil loading in coating, phr | Peel strength, pli |
|---|---|---|
| 24 | 0 | 5.37 |
| 25 | 2 | 6.05 |
| 26 | 4 | 6.40 |
| 27 | 6 | 6.67 |
| 28 | 8 | 6.68 |
| 29* | No coating on foil | 3.97 |

*Control

The data in Table 8 show that increasing the amount of filler from 0 to 8 phr in the elastomer solution results in a 1.3 pli increase in bond strength. Overall, the presence of the adhesion promoting layer increases bond strength by 1.4 to 2.7 pli.

### Example 30

A 6 wt % solution of Royalene 551/Royalene 301T (70/30, by weight) in xylene was prepared. Added to this solution were 5 phr Lupersol 130, 20 phr Saytex BT93, and 1 phr Mayzo BLS 1944, and 1 phr Naugard Q. The coatings were applied to 0.5-oz Circuit Foil TWS and the coating was allowed to air dry. An RO4350B prepreg was applied and heated under pressure to effect lamination.

### Example 31

Example 31 was prepared as in Example 30, but an additional component, B-3000, was added to the coating solution at a level of 10 phr.

### Example 32

Example is a comparative example, prepared as in Examples 30 and 31 except the 0.5-oz TWS is not coated with an adhesion promoting layer. The data for Examples 30-32 are shown in Table 9.

TABLE 9

| Example | B-3000 loading in foil coating, phr | Peel strength, pli |
|---|---|---|
| 30 | 0 | 5.51 |
| 31 | 10 | 6.14 |
| 32* | No coating on foil | 4.48 |

*Control

Adding B-3000 (a high-1,2-vinyl polybutadiene co-curing component) to the adhesion promoting layer increases the peel strength.

### Examples 33-37

Examples 33-37 were prepared as in Example 1. Varying amounts of Royalene 301 were applied to the TAX foil resulting in differing thicknesses of the adhesion promoting layer. Thicknesses and peel strengths of the various examples are shown in Table 10. Example 37 is a control in which no adhesion promoting layer was applied. Example 37 uses the same lot of copper as Examples 33-36 and has been included for an accurate comparison due to some variability in peel strength results between lots of copper foil.

TABLE 10

| Example | Coating weight, g/m² | Peel strength, pli |
|---|---|---|
| 33 | 1.42 | 4.48 |
| 34 | 3.82 | 5.52 |
| 35 | 5.66 | 5.54 |
| 36 | 8.12 | 5.78 |
| 37* | 0 | 4.24 |

*Control

As the above data show, the peel strength increases as thickness of the adhesion promoting layer increases.

### Examples 38-42

In the following examples, a silane, A-174 was applied to the copper foil TWX before application of the elastomer solution and/or application of the thermosetting composition. A 5 wt % solution of A-174 in acetone was sprayed on vertical copper sheets which were allowed to drain off excess solution. The sheets were then dried at 60° C. for 15 minutes. Examples 38 and 39 employ a 16.7 wt % solution of Kraton D1118X in xylene with 2 parts of Vulcup per 100 parts of elastomer. In Example 39 the elastomer solution additionally contains 1 part of A-189 silane per hundred parts of elastomer. Example 40 employs an 11.8 wt % solution of Taktene 1220 in xylene with 2 parts of Vulcup per 100 parts of elastomer. Example 41 employs a 16.7 wt % solution of Trilene 77 in xylene with 2 parts of Vulcup per 100 parts of elastomer and 1 part of A-189 per hundred parts of elastomer. Example 42 uses no elastomer solution at all.

Lamination conditions were as follows:

6.9 MPa (1000 psi) was maintained throughout lamination.
Temperature was ramped from ambient temperature to 93° C. at 2.8° C. per minute.
Temperature was ramped from 93° C. to 191° C. at 1.1° C. per minute.
Dwell at 191° C. for 120 minutes.
Temperature was ramped down to 66° C. at 1.2° C. per minute.

Peel strength results as well as the coating thickness of Examples 38-42 are shown in Table 11.

TABLE 11

| | Weight of Adhesion Promoting | |
|---|---|---|
| Example | Layer, g/m² | Peel strength, pli |
| 38 | 7.9 | 5.38 |
| 39 | 7.8 | 5.15 |
| 40 | 7.4 | 4.24 |
| 41 | 12.7 | 4.79 |
| 42* | — | 2.83 |

*Comparative example

The data in Table 11 show that when the copper foil is treated with silane or when silane is added to the elastomer solution, the presence of the adhesion promoting layer improves bond strength. Examples 38 through 41 shows improvements in bond strength of up to 90%. Example 41 employs an ethylene-propylene-diene monomer elastomer, Trilene 77, which is lower in molecular weight than styrene-butadiene rubber, Kraton D1118X, used in Examples 38 and 39. Example 41 shows less of an increase in bond strength than Examples 38 and 39 despite the use of more elastomer. Consequently, it appears that molecular weight of the elastomer may affect the bond strength of the laminate.

### Example 43

An 8 wt % solution of Royalene 551/Royalene 301T (70/30, by weight) in xylene was prepared. To this solution was added 5 phr Lupersol 130, 30 phr Saytex BT-93, and 0.15 phr BLS 1944. The coating formulation was coated onto 1/2-oz. TWS (Circuit Foil Luxembourg) and the weight uptake of the coating (dry) was 6 gsm. 20-Mil laminates were prepared with RO4350B prepreg.

### Example 44

A 20-mil comparative laminate was prepared using as a substrate an RO4350B prepreg and 1/2-oz. TWS (Circuit Foil Luxembourg). The dielectric constant and dissipation factor for these two examples are shown in Table 12. Test results for two specimens of each laminate construction are given. Measurements were made at 10 GHz in accordance with IPC-TM-650 2.5.5.5B.

TABLE 12

| Example | Dielectric Constant, Dk | Dissipation Factor, df |
|---|---|---|
| 43-1 | 3.451 | 0.00391 |
| 43-2 | 3.449 | 0.00418 |
| 44-1* | 3.457 | 0.00379 |
| 44-2* | 3.457 | 0.00369 |

*Comparative Examples

As may be seen by reference to the above data, use of an elastomer composition improves bond strength, but does not adversely affect the electrical properties of the laminates.

Although the copper-clad laminates described in the examples were prepared by applying the elastomer solution to the copper foil prior to lamination, it is anticipated that the elastomer solution could be applied to the curable thermosetting composition prior to lamination of the copper foil. It is also specifically envisioned that copper foils or thermosetting compositions can be pre-treated with the elastomer solution, dried, and stored until needed for lamination.

The endpoints of all ranges recited herein directed to the same property are independently combinable and inclusive of the endpoint. While preferred embodiments have been shown and described, various modifications and substitutions may be made thereto without departing from the spirit and scope of the invention. Accordingly, it is to be understood that the present invention has been described by way of illustration and not limitation.

1. A method of forming a low dielectric constant, low dissipation factor circuit material, comprising
disposing an adhesion promoting elastomer layer between a copper foil and a circuit substrate material; and
laminating the copper foil, adhesion promoting elastomer layer, and circuit substrate material to form the circuit material;
wherein the adhesion promoting elastomer layer comprises an elastomer and a non-sulfur curing agent.

2. The method of claim 1 wherein the elastomer comprises ethylene-propylene elastomer, ethylene-propylene-diene monomer elastomer, styrene-butadiene elastomer, styrene butadiene block copolymers, 1,4-polybutadiene, styrene-isoprene-styrene triblock copolymers, styrene-(ethylene-butylene)-styrene triblock copolymers, styrene-(ethylene-propylene)-styrene triblock copolymers, styrene-(ethylene-butylene) diblock copolymers, polyisoprene, elastomeric acrylate polymers, silicone elastomers, fluoropolymer elastomers, butyl rubber, urethane elastomers, norbornene based elastomers, dicyclobutadiene based elastomers, butadiene copolymers with acrylonitrile, acrylate esters, methacrylate esters, carboxylated vinyl monomers, copolymers of isoprene with acrylonitrile, copolymers of isoprene with acrylate esters, copolymers of isoprene with methacrylate esters, copolymers of isoprene with carboxylated vinyl monomers, or a mixture comprising at least one of the foregoing elastomers.

3. The method of claim 2 wherein the elastomer comprises ethylene-propylene-diene monomer elastomer.

4. The method of claim 3 wherein the ethylene-propylene-diene monomer elastomer comprises an ethylene content of at least about 30 wt % of the total weight of the ethylene-propylene-diene monomer elastomer.

5. The method of claim 1 wherein the cross-linking agent is dicumyl peroxide, alpha, alpha-di(t-butylperoxy)-m,p-diisopropylbenzene, 2,5-dimethyl-2,5-di(t-butylperoxy)hexane-3,2,5-dimethyl-2,5-di(t-butylperoxy)hexyne-3, or a mixture comprising one or more of the foregoing cross-linking agents.

6. The method of claim 1 wherein the elastomer composition further comprises a viscosity modifier, coupling agent, wetting agent, flame retardant, filler, co-curing component, anti-oxidant, or a mixture comprising one or more of the foregoing additives.

7. The method of claim 1 wherein the copper foil comprises a thermal barrier.

8. The method of claim 1 wherein the circuit substrate comprises a thermosetting resin or a mixture of thermosetting and thermoplastic resins.

9. The method of claim 1 wherein the circuit substrate comprises polybutadiene, polyisoprene, polybutadiene/polyisoprene copolymers, or a mixture comprising one or more of the foregoing resins.

10. The method of claim 1 wherein the adhesion promoting layer has a weight of about 3 to about 15 grams per square meter.

11. A method of making a low dielectric constant, low dissipation factor circuit material, comprising:
contacting a copper foil with an elastomer solution comprising a solvent, an elastomer composition, and a non-sulfur curing agent,
removing the solvent to form an adhesion promoting layer,
contacting the adhesion promoting layer with a curable thermosetting composition, and
laminating the copper foil, the adhesion promoting layer, and the thermosetting composition to form a circuit to form a circuit material having a dielectric constant of less than about 3.8 and a dissipation factor of less than about 0.007, each measured at a frequency of 1 and 10 gHz.

12. An article for forming a circuit material, comprising
a copper foil; and
an adhesion promoting elastomer composition in an amount of about 1 g/m² to about 15 g/m² disposed on a surface of the copper foil, wherein the adhesion promoting elastomer composition comprises an elastomer and a non-sulfur curing agent.

13. An article for forming a circuit material, comprising
a curable circuit substrate material; and
an adhesion promoting elastomer composition comprising an elastomer and a non-sulfur curing agent, wherein the adhesion promoting elastomer composition is disposed on at least a portion of a surface of the substrate composition, and wherein the cured circuit substrate material and elastomer composition have a dielectric constant of less than about 3.8 and a dissipation factor of less than about 0.007, each measured at frequencies from 1 to 10 gigahertz.

14. A circuit material, comprising
an adhesion promoting elastomer layer comprising an elastomer and a non-sulfur curing agent, wherein the adhesion promoting elastomer layer is disposed between a copper foil and a first side of a circuit substrate, and wherein the adhesion promoting elastomer layer and the circuit material together have a dielectric constant of less than about 3.8 and a dissipation factor of less than about 0.007, each measured at frequencies from 1 to 10 GHz.

15. The circuit material of claim 14, further comprising a second copper foil disposed on a second side of the circuit substrate.

16. The circuit material of claim 15, further comprising a second elastomer layer disposed between the second copper foil and the second side of the circuit substrate.

17. A circuit comprising:
a copper foil;
a first adhesion promoting elastomer layer comprising an elastomer and a non-sulfur curing agent;
a circuit substrate having a first and second side; and
a patterned circuit layer having a first and second side, wherein the copper foil is disposed on the first side of the circuit substrate material, the first side of the patterned circuit layer is disposed on the second side of the circuit substrate material, and the first adhesion promoting layer is disposed at least between the copper foil and the first side of the circuit substrate material or between the first side of the patterned circuit layer and the second side of the circuit substrate material.

18. The circuit of claim 17, further comprising a second copper foil and a bond ply having a first and second side, wherein the first side of the bond ply is disposed on the second side of the patterned circuit layer, and the second copper foil is disposed on the second side of the bond ply.

19. The circuit of claim 18, further comprising a second adhesion promoting elastomer layer comprising an elastomer and a non-sulfur curing agent, wherein the adhesion promoting elastomer layer is disposed between the second side of the bond ply and the second side of the copper foil.

20. The circuit of claim 17 further comprising a second adhesion promoting elastomer layer comprising an elastomer and a non-sulfur curing agent, wherein the first adhesion promoting layer is disposed between the copper foil and the first side of the circuit substrate material, and the second adhesion promoting layer is disposed between the patterned circuit and the second side of the circuit substrate material.

21. The circuit of claim 20, further comprising a second copper foil and a bond ply having a first and second side, wherein the first side of the bond ply is disposed on the second side of the patterned circuit layer, and the second copper foil is disposed on the second side of the bond ply.

22. The circuit of claim 21, further comprising a third adhesion promoting elastomer layer comprising an elastomer and a non-sulfur curing agent, wherein the adhesion promoting elastomer layer is disposed between the second side of the bond ply and the second copper foil.

23. A method of forming a low dielectric constant, low dissipation factor circuit material, comprising
disposing an adhesion promoting elastomer layer between a copper foil and a circuit substrate material; and
laminating the copper foil, adhesion promoting elastomer layer, and circuit substrate material to form the circuit material;
wherein the amount of adhesion promoting elastomer layer used is about 1 to about 3 g/m².

24. The method of claim 23 wherein the copper foil is a low profile copper foil.

25. A method of making a low dielectric constant, low dissipation factor circuit material, comprising:
contacting a copper foil with an elastomer solution comprising a solvent and an elastomer composition,
removing the solvent to form an adhesion promoting layer, wherein the adhesion promoting layer is present in an amount of about 1 to about 3 grams per square meter,
contacting the adhesion promoting layer with a curable thermosetting composition, and
laminating the copper foil, the adhesion promoting layer, and the thermosetting composition to form a circuit to form a circuit material having a dielectric constant of less than about 3.8 and a dissipation factor of less than about 0.007, each measured at a frequency from 1 to 10 gHz.

26. The method of claim 25 wherein the copper foil is a low profile copper foil.

27. An article for forming a circuit material, comprising
a copper foil; and
an adhesion promoting elastomer composition in an amount of about 1 g/m² to about 3 g/m² disposed on a surface of the copper foil.

28. The method of claim 1 wherein the copper foil is low profile copper foil.

29. An article for forming a circuit material, comprising
a curable circuit substrate material; and
an adhesion promoting elastomer composition, wherein the adhesion promoting elastomer composition is disposed on at least a portion of a surface of the substrate composition in an amount from about 1 g/m² to about 3 g/m², and wherein the cured circuit substrate material and elastomer composition have a dielectric constant of less than about 3.8 and a dissipation factor of less than about 0.007, each measured at a frequency from 1 to 10 gigahertz.

30. The method of claim 29 wherein the copper foil is a low profile copper foil.

31. A circuit material, comprising
an adhesion promoting elastomer layer in an amount from about 1 g/m² to about 3 g/m², wherein the adhesion promoting elastomer layer is disposed between a copper foil and a first side of a circuit substrate, and wherein the adhesion promoting elastomer layer and the circuit material together have a dielectric constant of less than about 3.8 and a dissipation factor of less than about 0.007, each measured at frequencies from 1 to 10 GHz.

32. The method of claim 31 wherein the copper foil is a low profile copper foil.

33. A circuit comprising:
a copper foil;
a first adhesion promoting elastomer layer in an amount from about 1 g/m² to about 3 g/m²;
a circuit substrate having a first and second side; and
a patterned circuit layer having a first and second side, wherein the copper foil is disposed on the first side of the circuit substrate material, the first side of the patterned circuit layer is disposed on the second side of the circuit substrate material, and the first adhesion promoting layer is disposed at least between the copper foil and the first side of the circuit substrate material or between the first side of the patterned circuit layer and the second side of the circuit substrate material.

34. The method of claim 33 wherein the copper foil is a low profile copper foil.
